(19) United States
(12) Patent Application Publication
(10) Pub. No.: US 2025/0359487 A1
(43) Pub. Date: Nov. 20, 2025

(54) SEMICONDUCTOR DEVICE AND METHOD FOR FORMING THE SAME

(71) Applicant: Taiwan Semiconductor Manufacturing Company, Ltd., Hsinchu (TW)

(72) Inventor: Chern-Yow Hsu, Hsin-Chu county (TW)

(73) Assignee: Taiwan Semiconductor Manufacturing Company, Ltd., Hsinchu (TW)

(21) Appl. No.: 18/666,777

(22) Filed: May 16, 2024

(51) Int. Cl. H10N 50/80; G11C 11/16; H10B 61/00; H10N 50/01; H10N 50/10

(52) U.S. Cl. CPC H10N 50/80; G11C 11/161; H10B 61/00; H10N 50/01; H10N 50/10

(57) ABSTRACT

A semiconductor device is provided. The semiconductor device includes a bottom electrode, a top electrode over the bottom electrode, and a data storage structure disposed between the top electrode and the bottom electrode. The semiconductor device further includes a top electrode via (TEVA) electrically coupling the top electrode, and a hard mask pattern disposed over the top electrode and surrounding the TEVA.

### BACKGROUND

Many modern-day electronic devices contain electronic memory, such as hard disk drives or random-access memory (RAM). Electronic memory may be volatile memory or non-volatile memory. Non-volatile memory is able to retain its stored data in the absence of power, whereas volatile memory loses its data memory contents when power is lost. Electronic memory can include data storage structures such as magnetic tunnel junctions (MTJs), which can be used in hard disk drives and/or RAM, and may be promising candidates for next generation memory solutions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic cross-sectional view of a semiconductor device according to some embodiments of the present disclosure.

FIG. 2A illustrates a schematic cross-sectional view of a semiconductor device including a plurality of memory regions according to some embodiments of the present disclosure.

FIG. 2B illustrates a schematic cross-sectional view of a semiconductor device including a plurality of memory regions according to some embodiments of the present disclosure.

FIG. 3 illustrates a schematic cross-sectional view of a semiconductor device including a memory cell region and a logic region according to some embodiments of the present disclosure.

FIGS. 4-10, FIG. 11A and FIG. 12 illustrate a series of schematic cross-sectional views of a method for forming a semiconductor device according to some embodiments of the present disclosure.

FIG. 11B illustrates a schematic top view taken along line A-A′ in FIG. 11A.

FIG. 13 illustrates a flowchart of some embodiments of a method consistent with FIGS. 4-12.

FIG. 14 illustrates a graphical representation of a titanium content analysis with respect to sidewalls of a data storage structure in a semiconductor device by using Energy Dispersive X-ray Analysis (EDX).

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A memory cell includes a data storage structure arranged between top and bottom electrodes. The data storage structure is able to store a bit of information as a logical “1” or a logical “0”. By applying an electrical bias to the memory cell and across the data storage structure, the bit may be switched from a logical “0” to a logical “1” and vice versa. A top electrode via (TEVA) electrically couples an interconnect structure to the top electrode, such that a power source can be supplied. Similarly, a bottom electrode via (BEVA) electrically couples another interconnect structure to the bottom electrode, such that an electrical bias can be applied.

During the formation of the memory cell, the top electrode may be used as a mask for etching a data storage stack. However, the top electrode mask is etched away simultaneously during the etching of the data storage stack, which causes conductive etching by-products from the top electrode mask to be re-deposited on sidewalls of the resulted data storage structure, leading to electrical short of the memory cell.

In the present disclosure, a method of manufacturing memory cells is presented to produce reliable memory cells. The new manufacturing method uses a hard mask for the second etch of the data storage structure. By replaces the top electrode mask with a hard mask, the new manufacturing method ensures that during the second etch of the data storage structure, no conductive by-product from the mask is re-deposited on sidewalls of the data storage structure, and thus prevents the memory cell from being electrically shorted. In doing so, the memory cell may reliably read, write, and store bits of information.

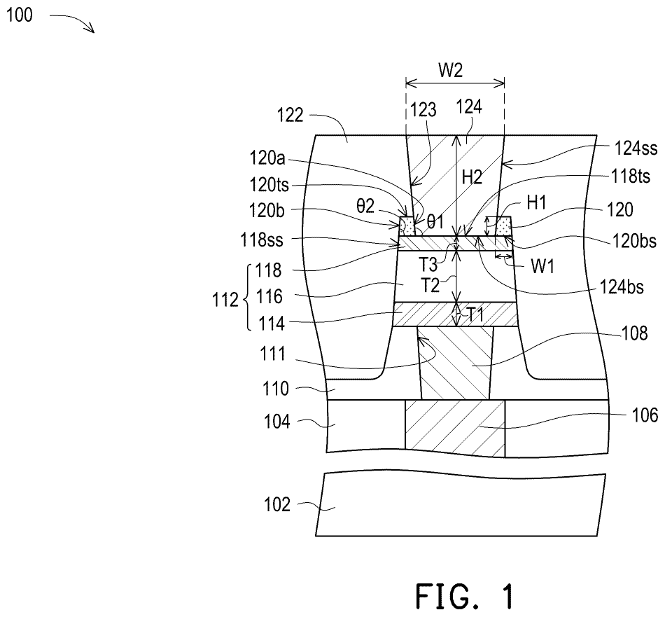

FIG. 1 illustrates a schematic cross-sectional view 100 of a semiconductor device according to some embodiments of the present disclosure. The semiconductor device includes a lower inter-layer dielectric (ILD) layer 104 disposed over a semiconductor substrate 102. The ILD layer 104 includes an underlying interconnect structure 106, and a bottom electrode via (BEVA) 108 overlies the underlying interconnect structure 106. A dielectric layer 110 overlies the underlying interconnect structure 106 and the ILD layer 104. In some embodiments, the dielectric layer 110 surrounds outer sidewalls of the BEVA 108. The BEVA 108 may extend through a hole 111 defined by inner sidewalls of the dielectric layer 110 and electrically couple the underlying interconnect structure 106 to a memory cell 112.

The memory cell 112 may include a bottom electrode 114 disposed over the BEVA 108 and a top electrode 118 disposed over the bottom electrode 114. The BEVA 108 underlying the bottom electrode 114 electrically couples the underlying interconnect structure 106 to the bottom electrode 114. In some embodiments, the BEVA 108 contacts a bottom surface of the bottom electrode 114, which continuously extends past the opposing outermost sidewalls of the BEVA 108. A data storage structure 116 is disposed between the bottom electrode 114 and the top electrode 118. The data storage structure 116 is configured to store a bit of data. In some embodiments, a dielectric structure 122 surrounds outer sidewalls of the top electrode 118, the bottom electrode 114, and the data storage structure 116. In some embodiments, the data storage structure 116 may be or otherwise include, for example, a magnetic tunnel junction (MTJ), a ferroelectric layer, or any other suitable data storage structure(s).

The bottom electrode 114 may be or otherwise include a conductive material, such as tantalum, titanium, tungsten, titanium nitride, tantalum nitride, or the like. In some embodiments, the bottom electrode 114 may have a thickness T1 ranging from approximately 5 nanometers to approximately 45 nanometers, from approximately 10 nanometers to approximately 30 nanometers, or other similar values. In some embodiments, the data storage structure 116 may have a thickness T2 ranging from approximately 10 nanometers to approximately 50 nanometers, from approximately 15 nanometers to approximately 40 nanometers, or other similar values. The top electrode 118 may be or otherwise include a conductive material, such as tantalum, titanium, tungsten carbide, titanium nitride, tantalum nitride, or the like. In some embodiments, the top electrode 118 may have a thickness T3 ranging from approximately 1 nanometer to approximately 15 nanometers, from approximately 2 nanometers to approximately 10 nanometers, or other similar values. The thickness T3 of the top electrode 118 may be less than or equal to the thickness T2 of the data storage structure 116. In some embodiments, a ratio of the thickness T3 of the top electrode 118 to the thickness T2 of the data storage structure 116 is from approximately 0.1 to approximately 1.0, for example, from approximately 0.2 to approximately 0.8. In some embodiments, a ratio of the thickness T3 of the top electrode 118 to the thickness T1 of the bottom electrode 114 ranges from approximately 0.2 to approximately 2.0, for example, from approximately 0.5 to approximately 1.5.

The semiconductor device further includes a top electrode via (TEVA) 124 overlies the memory cell 112. In some embodiments, the dielectric structure 122 surrounds outer sidewalls of the TEVA 124. The TEVA 124 may electrically couple the top electrode 118 of the memory cell 112 to another interconnect structure or an external power source. In some embodiments, the TEVA 124 contacts a top surface 118ts of the top electrode 118. The TEVA 124 may extend through a hole 123 defined by inner sidewalls of the dielectric structure 122. In some embodiments, the TEVA 124 may be or otherwise include, for example, tantalum, tantalum nitride, titanium, titanium nitride, tungsten carbide, or some other suitable material(s). In some embodiments, the TEVA 124 and the corresponding hole 123 respectively have a width W2. In some embodiments, the width W2 of the TEVA 124 is measured at a top surface of the TEVA 124. In some embodiments, the width W2 is a maximum width of the TEVA 124 and the corresponding hole 123. The width W2 may range from approximately 10 nanometers to approximately 100 nanometers, from approximately 20 nanometers to approximately 80 nanometers, or other similar values. In some embodiments, the TEVA 124 has a height H2 ranging from approximately 5 nanometers to approximately 70 nanometers, from approximately 10 nanometers to approximately 50 nanometers, or other similar values.

The semiconductor device further includes a hard mask pattern 120 overlies the top electrode 118 of the memory cell 112. The hard mask pattern 120 is a remaining portion of a patterned hard mask that includes a non-conductive material and used in the etching for the formation of the data storage structure 116. The hard mask pattern 120 may be or otherwise an insulating material, such as silicon dioxide, silicon nitride, silicon carbide or the like, or any combination of the foregoing. The patterned hard mask doesn't produce conductive by-product during the etching for the formation of the data storage structure 116 so that re-deposition of conductive by-product onto sidewalls of the data storage structure 116 can be avoided to improve device reliability. The hard mask pattern 120 may cover a periphery of the top electrode 118. In some embodiments, the hard mask pattern 120 is completely overlapped with the top electrode 118. In some embodiments, the hard mask pattern 120 surrounds the TEVA 124. For example, the hard mask pattern 120 extends along sidewalls of the TEVA 124. In some embodiments, the hard mask pattern 120 contacts a bottom portion of the sidewalls of the TEVA 124. In some embodiments, the hard mask pattern 120 contacting both the top surface 118ts of the top electrode 118 and a side surface 124ss of the TEVA 124. The hard mask pattern 120 may have a height H1 ranging from approximately 2 nanometers to approximately 10 nanometers, from approximately 3 nanometers to approximately 8 nanometers, or other similar values. In some embodiments, the hard mask pattern 120 has a width W1 measured at one side of the TEVA 124. The width W1 may be measured at a bottom surface 120bs of the hard mask pattern 120. In some embodiments, the width W1 ranges from approximately 16 nanometers to approximately 100 nanometers, from approximately 30 nanometers to approximately 70 nanometers, or other similar values.

In some embodiments, the side surface 124ss of the TEVA 124 are slanted at an angle θ1. In some embodiments, the angle θ1 may be an obtuse angle as measured with respect to a bottom surface 124bs of the TEVA 124. The TEVA 124 may include opposing outer sidewalls tilted at the angle θ1. In some embodiments, the angle θ1 may range from approximately 90 degrees to approximately 120 degrees, from approximately 95 degrees to approximately 110 degrees, or other similar values as measured through the TEVA 124 and with respect to the top surface 118ts of the top electrode 118.

In some embodiments, the hard mask pattern 120 includes a side surface 120a contacting the side surface 124ss of the TEVA 124. In some embodiments, an outer side surface 120b of the hard mask pattern 120 opposite to the side surface 120a is slanted at an angle θ2 measured with respect to the top surface 118ts of the top electrode 118. In some embodiments, the angle θ2 may be an acute angle. For example, the angle θ2 may range from approximately 70 degrees to approximately 90 degrees, from approximately 75 degrees to approximately 85 degrees, or other similar values. In further embodiments, the bottom surface 120bs of the hard mask pattern 120 is laterally aligned with the bottom surface 124bs of the TEVA 124. In other words, the bottom surface 120bs of the hard mask pattern 120 is flush with the bottom surface 124bs of the TEVA 124. In some embodiments, the outer side surface 120b of the hard mask pattern 120 and a side surface 118ss of the top electrode 118 forms a continuous surface.

The ILD layer 104 laterally extends to non-zero distances past opposing sides of the underlying interconnect structure 106. By extending past opposing sides of the underlying interconnect structure 106, the ILD layer 104 is able to prevent the exposure of the underlying interconnect structure 106 during etching processes used to manufacture the memory cell 112. Similarly, the dielectric layer 110 laterally extends to non-zero distances past opposing sides of the BEVA 108. By extending past opposing sides of the BEVA 108, the dielectric layer 110 is able to prevent the exposure of the BEVA 108 during etching processes used to manufacture the memory cell 112. In some embodiments, a bottommost surface of the bottom electrode 114 continuously extends past opposing outermost sidewalls of the BEVA 108.

By implementing a non-zero lateral distance between the BEVA 108 and the outer sidewalls of the dielectric layer 110 and between the underlying interconnect structure 106 and outer sidewalls of the ILD layer 104, the semiconductor device ensures that during an etch of the data storage structure 116, no conductive by-product from the BEVA 108 and/or the underlying interconnect structure 106 is re-deposited on sidewalls of the data storage structure.

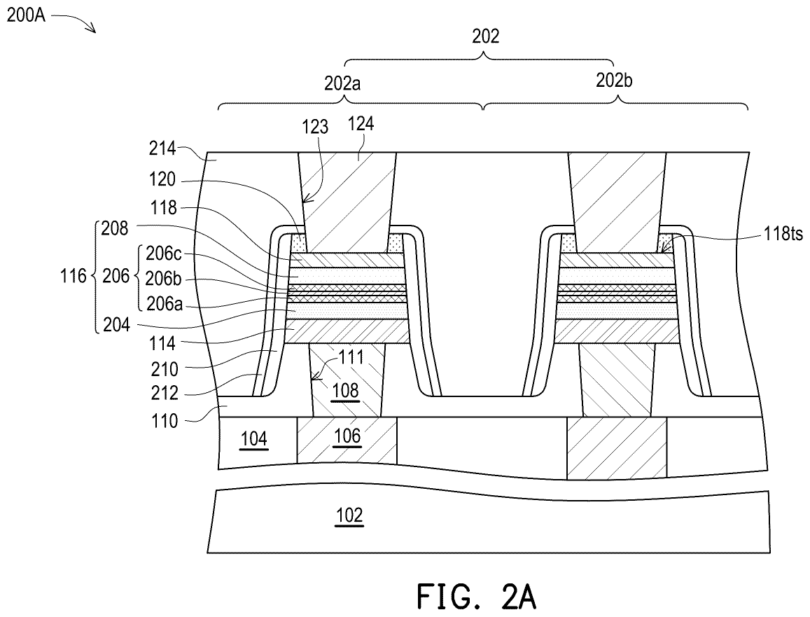

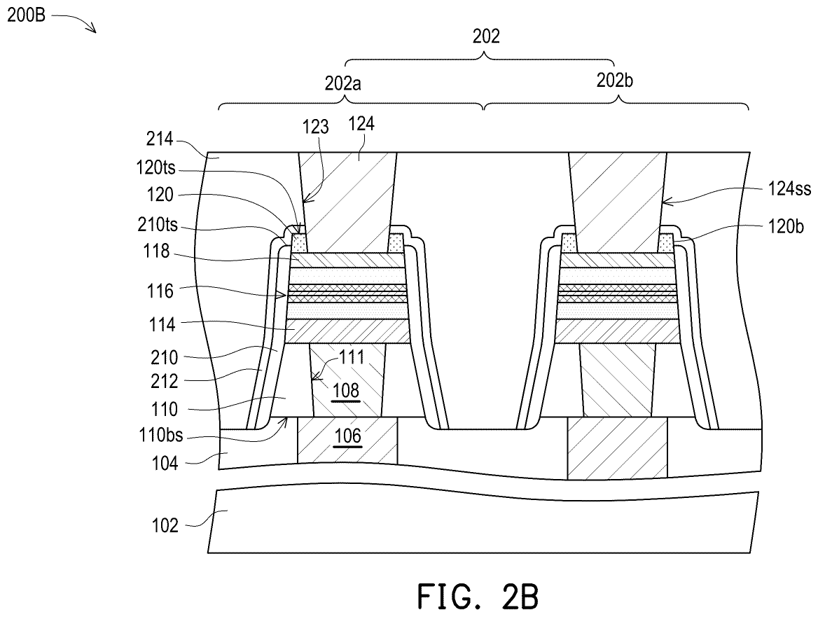

FIG. 2A illustrates a schematic cross-sectional view 200A of a semiconductor device including a plurality of memory regions according to some embodiments of the present disclosure. The semiconductor device includes a lower inter-layer dielectric (ILD) layer 104 disposed over a semiconductor substrate 102. A plurality of memory regions 202 overlie the ILD layer 104. The plurality of memory regions 202 include a first memory region 202a and a second memory region 202b. In some embodiments, the plurality of memory regions 202 may include additional memory regions. The plurality of memory regions 202 respectively include an underlying interconnect structure 106 disposed within the ILD layer 104, and a BEVA 108 overlying the underlying interconnect structure 106.

A dielectric layer 110 is disposed over the ILD layer 104 and the underlying interconnect structure 106. A bottom electrode via (BEVA) 108 extends through a hole 111 defined by inner sidewalls of the dielectric layer 110. A bottom electrode 114 overlies the BEVA 108 and the dielectric layer 110. A top electrode 118 overlies the bottom electrode 114, and a data storage structure 116 is disposed between the bottom electrode 114 and the top electrode 118. The data storage structure 116 is configured to store a bit of data. In some embodiments, a bit of data may be written to the data storage structure 116 by providing an electrical bias across the data storage structure 116.

In some embodiments, the data storage structure 116 includes a magnetic tunnel junction (MTJ) 206 that includes a pinned ferromagnetic layer 206a underlying and separated from a free ferromagnetic layer 206c by a tunnel dielectric layer 206b. The pinned ferromagnetic layer 206a has a fixed magnetization direction, and the free ferromagnetic layer 206c has a dynamic magnetization direction. In further embodiments, the data storage structure 116 further includes a seed layer 204 underlying the MTJ 206 and separating the MTJ 206 from the bottom electrode 114. The seed layer 204 may promote crystalline growth of the MTJ 206. In further embodiments, the data storage structure 116 further includes a capping layer 208 overlying the MTJ 206 and separating the MTJ 206 from the top electrode 118. The capping layer 208 protects the MTJ 206 from exposure to gas and/or moisture. The capping layer 208 further prevents metal from diffusing into the MTJ 206.

In some embodiments wherein the data storage structure 116 includes the MTJ 206, the dynamic magnetization direction of the free ferromagnetic layer 206c can be switched by applying an electrical bias across the tunnel dielectric layer 206b. By applying a current in a first direction from the free ferromagnetic layer 206c to the pinned ferromagnetic layer 206a, electrons with a magnetization direction the same as that of the pinned ferromagnetic layer 206a flow into and accumulate in the free ferromagnetic layer 206c, causing the magnetization of the free ferromagnetic layer 206c to be parallel to the pinned ferromagnetic layer 206a, writing the MTJ 206 to a low resistance state, representing the bit of data as a logical ‘0’. By applying a current in a second direction from the pinned ferromagnetic layer 206a to the free ferromagnetic layer 206c, electrons with a magnetization direction opposite that of the pinned ferromagnetic layer 206a flow into and accumulate in the free ferromagnetic layer 206c, causing the magnetization of the free ferromagnetic layer 206c to be antiparallel to the pinned ferromagnetic layer 206a, writing the MTJ 206 to a high resistance state, representing the bit of data as a logical ‘1’. By measuring the resistance across the MTJ 206, this bit of data can be read.

The semiconductor device further includes a hard mask pattern 120 and a top electrode via (TEVA) 124 overlies the top electrode 118. In some embodiments, the hard mask pattern 120 extends along a bottom portion of sidewalls of the TEVA 124. In some embodiments, a sidewall spacer 210 is extended along sidewalls of the bottom electrode 114, the data storage structure 116, the top electrode 118 and the hard mask pattern 120. In some embodiments, the hard mask pattern 120 is sandwiched between the sidewall spacer 210 and the TEVA 124. In some embodiments, the sidewall spacer 210 is disposed along opposing sidewalls of the bottom electrode 114, the data storage structure 116, the top electrode 118 and the hard mask pattern 120. Due to the existence of the hard mask pattern 120, the sidewall spacer 210 may protrude upward beyond the top surface 118ts of the top electrode 118.

In some embodiments, an etch stop layer 212 overlies the sidewall spacer 210 and the hard mask pattern 120. In some embodiments, the etch stop layer 212 contacts outer sidewalls of the TEVA 124. In some embodiments, the hard mask pattern 120 is sandwiched between the etch stop layer 212 and the top electrode 118 in a direction normal to the top surface of the top electrode 118. In other words, the hard mask pattern 120 separates the etch stop layer 212 from the top electrode 118. In some embodiments, the sidewall spacer 210 is sandwiched between the etch stop layer 212 and the hard mask pattern 120. In some embodiments, the etch stop layer 212 continuously extends from over the sidewall spacer 210 to below the bottom electrode 114.

In some embodiments, a dielectric layer 214 covers the dielectric layer 110 and the etch stop layer 212, and surrounds outer sidewalls of the etch stop layer 212 and the TEVA 124. In some embodiments, the dielectric layer 214 covers the etch stop layer 212 and contacts sidewalls of the TEVA 124. In some embodiments, the etch stop layer 212 shares a curved sidewall with the dielectric layer 214. In some embodiments, the dielectric layer 214 continuously extends over the first memory region 202a and the second memory region 202b.

FIG. 2B illustrates a schematic cross-sectional view 200B of a semiconductor device including a plurality of memory regions according to some embodiments of the present disclosure. As shown in the cross-sectional view 200B of FIG. 2B, in some embodiments, a sidewall spacer 210 disposed along opposing sidewalls of the hard mask pattern 120, the top electrode 118, the data storage structure 116, and the bottom electrode 114. A top surface 210ts of the sidewall spacer 210 may be below a top surface 120ts of the hard mask pattern 120 such that the etch stop layer 212 also contacts the outer side surface 120b of the hard mask pattern 120. In some embodiments, the sidewall spacer 210 continuously extends downward to the ILD layer 104, such that the sidewall spacer 210 completely covers opposing sidewalls of the dielectric layer 110. In some embodiments, the sidewall spacer 210 extends to vertically below a bottom surface 110bs of the dielectric layer 110.

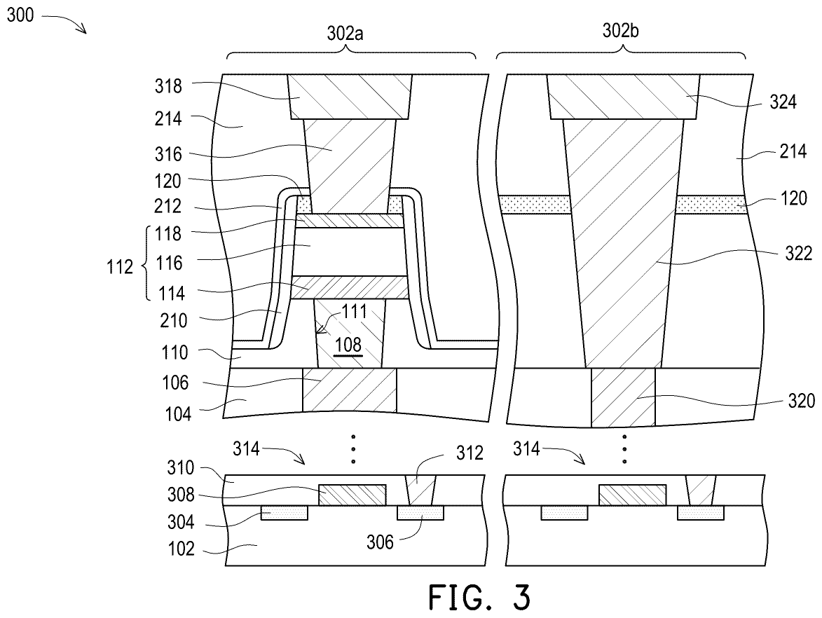

FIG. 3 illustrates a schematic cross-sectional view 300 of a semiconductor device including a memory cell region and a logic region according to some embodiments of the present disclosure. The semiconductor device includes a memory cell region 302a and a logic region 302b. Both the memory cell region 302a and the logic region 302b include a transistor structure 314 disposed in a semiconductor substrate 102. In various embodiments, the transistor structure 314 may include a field effect transistor (FET), a planar FET, a finFET, a gate all around structure (GAA) transistor, or the like. The transistor structure 314 includes heavily doped regions such as a source 304 and a drain 306 disposed within the semiconductor substrate 102. A gate structure 308 is disposed over a top surface of the semiconductor substrate 102 and between the source 304 and the drain 306. A lower inter-layer dielectric (ILD) layer 310 is disposed over the semiconductor substrate 102 and surrounding outer sidewalls of the gate structure 308. A contact plug 312 is disposed within the lower ILD layer 310. In some embodiments, the contact plug 312 is electrically coupled to the transistor structure 314. In further embodiments, the contact plug 312 may be electrically coupled to the drain 306. In some embodiments, the gate structure 308 may include a conductive gate electrode that is separated from the semiconductor substrate 102 by a gate dielectric layer (not shown).

The memory cell region 302a includes an ILD layer 104 overlying the lower ILD layer 310. The ILD layer 104 surrounds an underlying interconnect structure 106. In some embodiments, the underlying interconnect structure 106 is electrically coupled to the transistor structure 314 of the memory cell region 302a. A bottom electrode via (BEVA) 108 overlies the underlying interconnect structure 106 and extends through a hole 111 defined by inner sidewalls of the dielectric layer 110.

A bottom electrode 114 contacts a top surface of the BEVA 108. A data storage structure 116 overlies the bottom electrode 114, a top electrode 118 overlies the data storage structure 116, and a hard mask pattern 120 overlies the top electrode 118. The bottom electrode 114, the data storage structure 116 and the top electrode 118 may constitute a memory cell 112. A sidewall spacer 210 is disposed along sidewalls of the data storage structure 116, sidewalls of the top electrode 118, and sidewalls of the bottom electrode 114. In some embodiments, the sidewall spacer 210 is further disposed along sidewalls of the hard mask pattern 120. In some embodiments, the sidewall spacer 210 is further disposed along sidewalls of the dielectric layer 110. An etch stop layer 212 overlies the sidewall spacer 210 and the hard mask pattern 120. A top electrode via (TEVA) 316 overlies the top electrode 118 and electrically couples the top electrode 118 to a first overlying interconnect structure 318. In some embodiments, the TEVA 316 is narrower than the top electrode 118. In some embodiments, a bottom surface of the first overlying interconnect structure 318 overlies the TEVA 316 and extends laterally past opposing sidewalls of the TEVA 316. A dielectric layer 214 overlies the etch stop layer 212 and surrounds outer sidewalls of the TEVA 316 and the first overlying interconnect structure 318.

The logic region 302b includes an underlying interconnect structure 320 disposed within the ILD layer 104. In some embodiments, the underlying interconnect structure 320 is electrically coupled to transistor structure 314 of the logic region 302b. An inter-tier interconnect structure 322 may overly the underlying interconnect structure 320 in the logic region 302b. In some embodiments, the inter-tier interconnect structure 322 is disposed within the dielectric layer 214 and electrically couples the underlying interconnect structure 320 to a second overlying interconnect structure 324. In some embodiments, the inter-tier interconnect structure 322 in the logic region 302b is disposed at substantially the same level as the memory cell 112 in the memory cell region 302a. In some embodiments, the inter-tier interconnect structure 322 has a maximum width at a top surface of the inter-tier interconnect structure 322. In certain embodiments, the hard mask pattern 120 in the logic region 302b is embedded in the dielectric layer 214 and surrounds the inter-tier interconnect structure 322.

In some embodiments, the contact plug 312, the first overlying interconnect structure 318, the underlying interconnect structure 320, the inter-tier interconnect structure 322, and the second overlying interconnect structure 324 are conductive and may be or otherwise include, for example, tungsten, aluminum copper, copper, aluminum, some other suitable metal(s), or some other suitable conductive material(s). The lower ILD layer 310 may be or otherwise include, for example, nitride (e.g., silicon nitride, silicon oxynitride), a carbide (e.g., silicon carbide), an oxide (e.g., silicon oxide), borosilicate glass (BSG), phosphoric silicate glass (PSG), borophosphosilicate glass (BPSG), a low-k oxide (e.g., a carbon doped oxide, SiCOH), or some other suitable material(s). The gate structure 308 may be or otherwise include, for example, doped polysilicon, metal, or some other suitable conductive material(s).

In some embodiments, the TEVA 316 may be or otherwise include, for example, tantalum, tantalum nitride, titanium, titanium nitride, tungsten carbide, or some other suitable material(s). In some embodiments, the BEVA 108 may include a conductive material having a relatively low diffusivity (e.g., less than or equal to approximately 10⁻⁹ cm²/s, less than or equal to approximately 10⁻¹⁰ cm²/s, less than or equal to approximately 10⁻¹¹ cm²/s, or other similar values) and a relatively low resistivity (e.g., less than or equal to approximately 15 μ (micron)-Ohm-cm, less than or equal to approximately 10 μ-Ohm-cm, less than or equal to approximately 5 μ-Ohm-cm, or other similar values). In various embodiments, the conductive material of the BEVA 108 may be or otherwise include, for example, tungsten, nickel, cobalt, platinum, gold, iron, or the like.

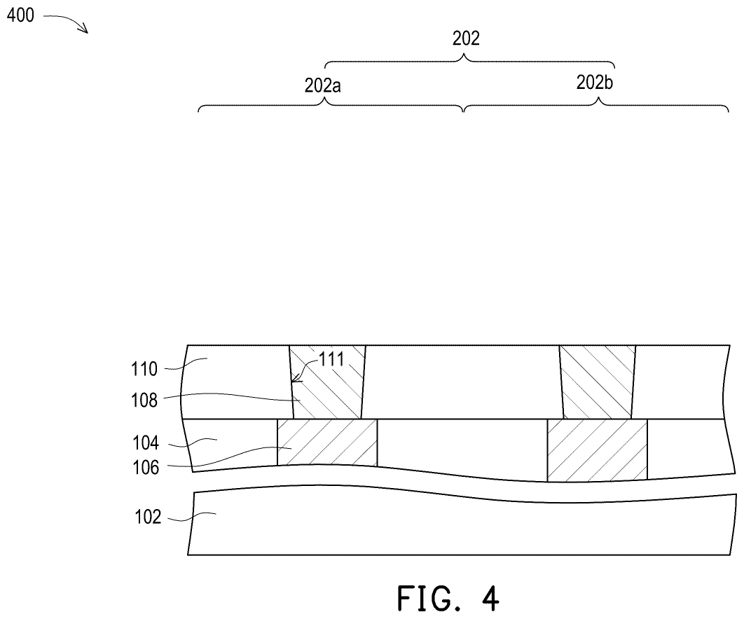

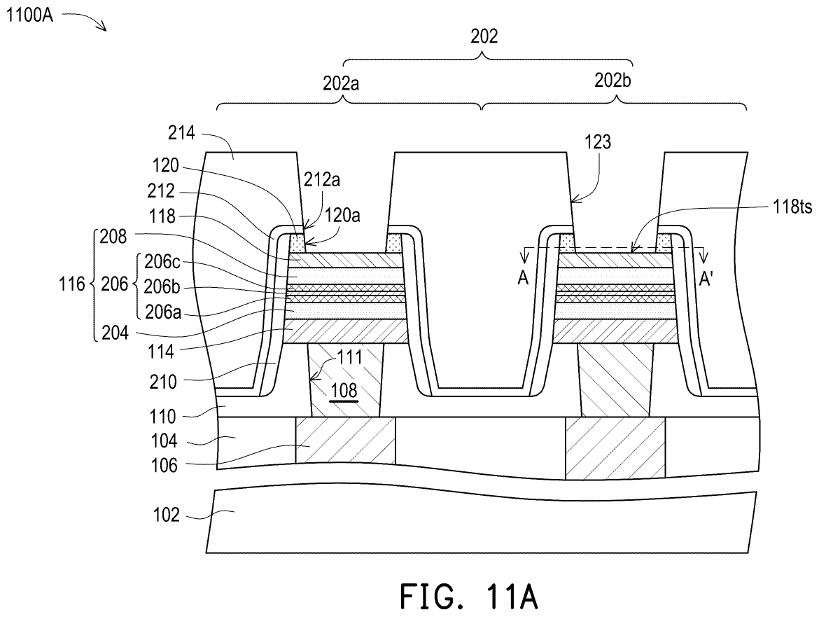

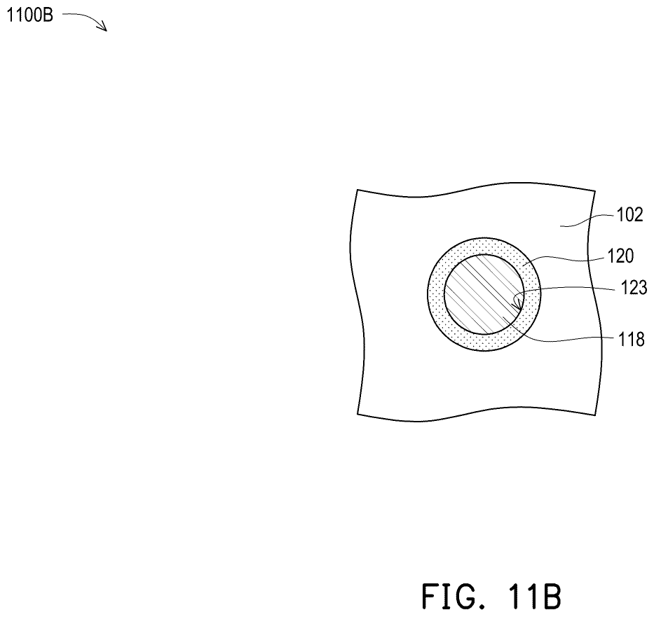

FIGS. 4-10, FIG. 11A and FIG. 12 illustrate a series of schematic cross-sectional views of a method for forming a semiconductor device according to some embodiments of the present disclosure. FIG. 11B illustrates a schematic top view taken along line A-A′ in FIG. 11A. With reference to FIGS. 4-12, a series of schematic cross sections 400-1200 illustrate some embodiments of a method for forming a semiconductor device including a plurality of memory regions 202 with reduced shorting due to re-deposition of a conductive material during manufacturing. Although FIGS. 4-12 are described in relation to a method, it will be appreciated that the structures disclosed in FIGS. 4-12 are not limited to such a method, but instead may stand alone as structures independent of the method.

As illustrated by the cross-sectional view 400 of FIG. 4, underlying interconnect structures 106 are formed within an inter-layer dielectric (ILD) layer 104 over a semiconductor substrate 102. For example, the plurality of memory regions 202 include a first memory region 202a and a second memory region 202b. In some embodiments, the plurality of memory regions 202 may include additional memory regions. The plurality of memory regions 202 may respectively include an underlying interconnect structure 106 disposed within the ILD layer 104.

In some embodiments, the semiconductor substrate 102 may be or otherwise include, for example, a bulk silicon substrate, a bulk germanium substrate, a group III-V substrate, or some other suitable semiconductor substrate. In some embodiments, the ILD layer 104 may be or otherwise include, for example, nitride (e.g., silicon nitride, silicon oxynitride), a carbide (e.g., silicon carbide), an oxide (e.g., silicon oxide), borosilicate glass (BSG), phosphoric silicate glass (PSG), borophosphosilicate glass (BPSG), a low-k oxide (e.g., a carbon doped oxide, SiCOH), or some other suitable material(s). In some embodiments, the underlying interconnect structure 106 is conductive, and may be or otherwise include, for example, tungsten, aluminum copper, copper, aluminum, some other suitable metal(s), or some other suitable conductive material(s).

In some embodiments, the ILD layer 104 may be formed by way of a deposition process (e.g., a chemical vapor deposition (CVD) process, a plasma enhanced CVD process, a physical vapor deposition process, or the like). In some embodiments, the underlying interconnect structure 106 may be formed by way of a damascene process (e.g., a single damascene process, a dual damascene process), in which the ILD layer 104 is selectively patterned to form a hole that is subsequently filled with a conductive material.

As further illustrated by the cross-sectional view 400 of FIG. 4, a dielectric layer 110 is formed over the ILD layer 104 and the underlying interconnect structure 106, and bottom electrode vias (BEVA) 108 are formed within the dielectric layer 110. The dielectric layer 110 may be formed by way of a deposition process (e.g., a chemical vapor deposition (CVD) process, a plasma enhanced CVD process, a physical vapor deposition process, or the like). In some embodiments, the dielectric layer 110 may be or otherwise include, for example, silicon dioxide, silicon nitride, some other suitable low-k dielectric(s), or any combination of the foregoing.

In some embodiments, the BEVA 108 is formed by depositing a conductive material within respective holes 111 of the dielectric layer 110 in the plurality of memory regions 202. In various embodiments, the conductive material may be deposited by a deposition process that may be or otherwise include, for example, chemical vapor deposition, physical vapor deposition, sputtering, and/or a plating process (e.g., an electroplating process, an electro-less plating process). In some embodiments, the conductive material may be or otherwise include, for example, tungsten, nickel, cobalt, platinum, gold, iron, or some other suitable conductive material(s). A planarization process is subsequently performed to remove the conductive material from over a top surface of the dielectric layer 110 to form the BEVA 108 in the hole 111. The planarization process may be or otherwise include, for example, a chemical-mechanical planarization (CMP), grinding, an etch, or some other suitable process.

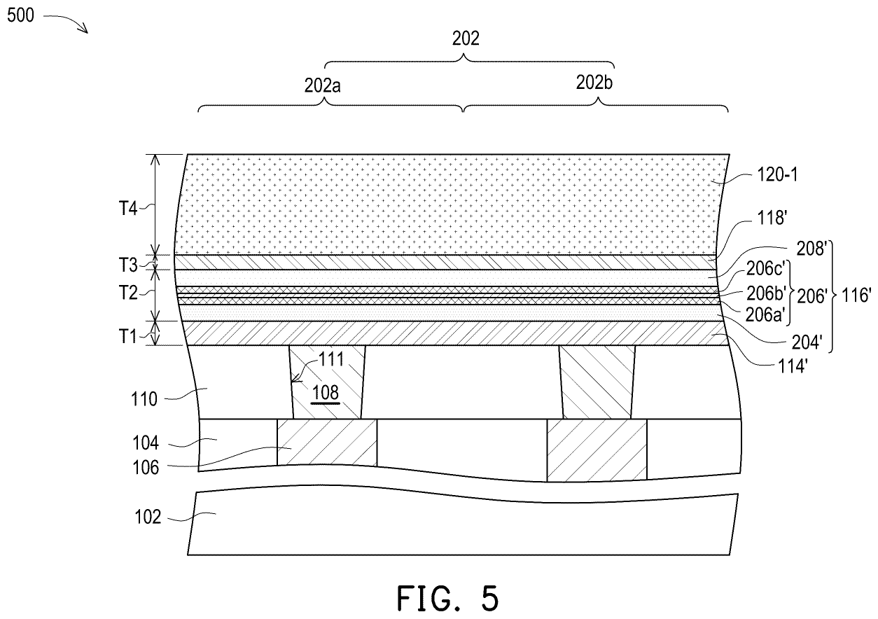

As illustrated by the cross-sectional view 500 of FIG. 5, a bottom electrode layer 114′ is formed over the dielectric layer 110 and the BEVA 108, such that the bottom electrode layer 114′ continuously extends to respective ones of the plurality of memory regions 202. The bottom electrode layer 114′ may be or otherwise include, for example, tantalum, titanium, tungsten, titanium nitride, tantalum nitride, or the like. The bottom electrode layer 114′ may be formed by, for example, chemical vapor deposition, physical vapor deposition, sputtering, and/or a plating process (e.g., an electroplating process, an electro-less plating process). In some embodiments, the bottom electrode layer 114′ may have a thickness T1 ranging from approximately 5 nanometers to approximately 45 nanometers, from approximately 10 nanometers to approximately 30 nanometers, or other similar values.

As further illustrated by the cross-sectional view 500 of FIG. 5, a data storage stack 116′ is formed over the bottom electrode layer 114′, such that the data storage stack 116′ continuously extends to respective ones of the plurality of memory regions 202. In some embodiments, the formation of the data storage stack 116′ includes the following steps: a seed layer 204′ is formed over the bottom electrode layer 114′; a MTJ structure 206′ is formed over the seed layer 204′, and a capping layer 208′ is formed over the MTJ structure 206′. In further embodiments, the formation of the MTJ structure 206′ includes the following steps: a pinned ferromagnetic layer 206a′ is formed over the seed layer 204′, a tunnel dielectric layer 206b′ is formed over the pinned ferromagnetic layer 206a′, and a free ferromagnetic layer 206c′ is formed over the tunnel dielectric layer 206b′. The free ferromagnetic layer 206c′ and the pinned ferromagnetic layer 206a′ may be or otherwise include, for example, a cobalt-iron-boron alloy, a cobalt-iron alloy, a nickel-iron alloy, or any suitable ferromagnetic material(s). The tunnel dielectric layer 206b′ may be or otherwise include, for example, magnesium oxide, another suitable oxide, or any suitable dielectric material(s). The seed layer 204′ may be or otherwise include, for example, tantalum nitride, magnesium, cobalt, nickel, chromium, platinum, manganese, some other suitable material(s), or a combination of the foregoing. The capping layer 208′ may be or otherwise include, for example, ruthenium, molybdenum, cobalt, iron, boron, magnesium, magnesium oxide, some other suitable material(s), or a combination of the foregoing. The seed layer 204′, the capping layer 208′, the free ferromagnetic layer 206c′, the tunnel dielectric layer 206b′, and the pinned ferromagnetic layer 206a′ may be formed by, for example, deposition processes (e.g., a chemical vapor deposition (CVD) process, a plasma enhanced CVD process, a physical vapor deposition process, or the like). The data storage stack 116′ may have a thickness T2 ranging from approximately 10 nanometers to approximately 50 nanometers, from approximately 20 nanometers to approximately 35 nanometers, or other similar values.

As further illustrated by the cross-sectional view 500 of FIG. 5, a top electrode layer 118′ is formed over the data storage stack 116′, such that the top electrode layer 118′ continuously extends to respective ones of the plurality of memory regions 202. The top electrode layer 118′ may be or otherwise include a conductive material, such as tantalum, titanium, tungsten carbide, titanium nitride, tantalum nitride, or the like. The top electrode layer 118′ may be formed by, for example, chemical vapor deposition, physical vapor deposition, sputtering, and/or a plating process (e.g., an electroplating process, an electro-less plating process). In some embodiments, the top electrode layer 118′ may be formed to have a thickness T3 ranging from approximately 1 nanometer to approximately 15 nanometers, from approximately 2 nanometers to approximately 10 nanometers, or other similar values.

As further illustrated by the cross-sectional view 500 of FIG. 5, a hard mask layer 120-1 is formed over the top electrode layer 118′, such that the hard mask layer 120-1 continuously extends to respective ones of the plurality of memory regions 202. The hard mask layer 120-1 may be or otherwise include a non-conductive material or an insulating material, such as silicon dioxide, silicon nitride, silicon carbide or the like, or any combination of the foregoing. In other words, the hard mask layer 120-1 and the top electrode layer 118′may comprise different materials. The hard mask layer 120-1 may be formed by way of a deposition process (e.g., a chemical vapor deposition (CVD) process, a plasma enhanced CVD process, a physical vapor deposition process, or the like). In some embodiments, the hard mask layer 120-1 may be formed to have a thickness T4 greater than a sum of the thickness T1 of the bottom electrode layer 114′ and the thickness T2 of the data storage stack 116′, but the present disclosure is not limited thereto. For example, the thickness T4 of the hard mask layer 120-1 may range from approximately 10 nanometers to approximately 200 nanometers, from approximately 15 nanometers to approximately 150 nanometers, or other similar values.

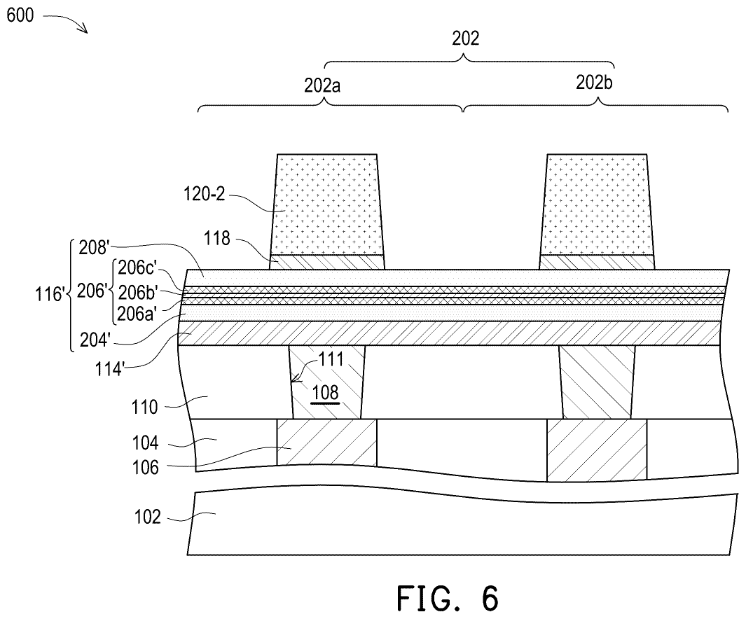

As illustrated by the cross-sectional view 600 of FIG. 6, the hard mask layer 120-1 and the top electrode layer 118′ is patterned by a first etching process. In some embodiments (not shown), the first etching process may be performed by forming a mask (e.g., a hard mask, a photoresist, or the like) over the hard mask layer 120-1, then exposing the hard mask layer 120-1 to an etchant according to the mask to define a pattern for the hard mask layer 120-1 and the top electrode layer 118′. In some embodiments, the hard mask layer 120-1 is patterned to form a patterned hard mask 120-2 in separate portions overlying the BEVA 108 in respective ones of the plurality of memory regions 202, and the top electrode layer 118′ is patterned to form a top electrode 118 in separate portions overlying the BEVA 108 in respective ones of the plurality of memory regions 202. The mask is then removed after performing the first etching process.

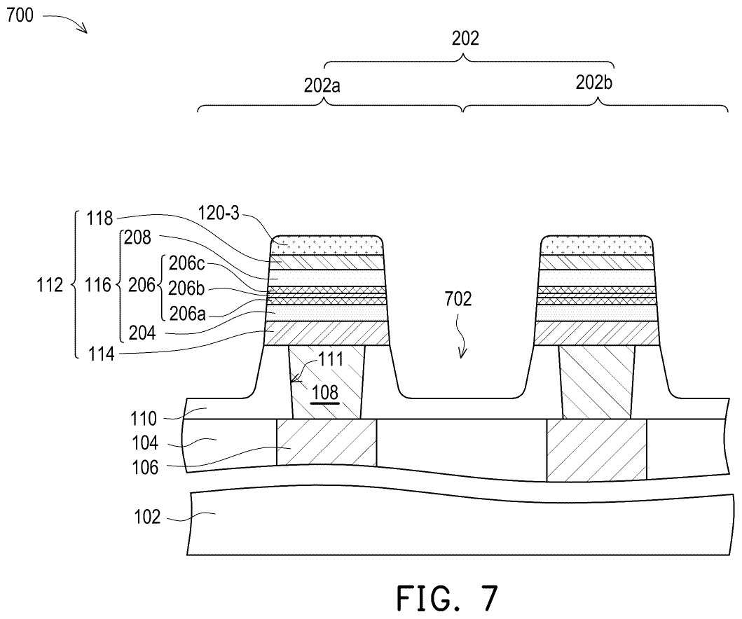

As illustrated by the cross-sectional views 600 and 700 of FIGS. 6-7, a second etching process is performed by using the patterned hard mask 120-2 as a hard mask, and exposing the data storage stack 116′ to an etchant according to the patterned hard mask 120-2. In some embodiments, the second etching process is ion beam etch (IBE). In some embodiments, the data storage stack 116′ and the bottom electrode layer 114′ are etched according to the patterned hard mask 120-2 by the second etching process to respectively form a data storage structure 116 and a bottom electrode 114, such that respective ones of the plurality of memory regions 202 include the individual data storage structure 116 and the individual bottom electrode 114. The second etching process may etch the patterned hard mask 120-2 simultaneously. Since the patterned hard mask 120-2 is composed of a non-conductive material, no conductive by-product from the hard mask will be re-deposited on sidewalls of the data storage structure during the etching of the data storage stack 116′, thereby preventing the memory cell from being electrically shorted.

In some embodiments, as described above, the thickness T4 of the hard mask layer 120-1 is greater than the sum of the thickness T1 of the bottom electrode layer 114′ and the thickness T2 of the data storage stack 116′ such that a patterned hard mask 120-3 remains on the top electrode 118 after the second etching process. In some embodiments, the second etching process further etches a portion of the dielectric layer 110 to form a recess 702 in the dielectric layer 110, such that the recess 702 separates the memory cell 112 in the first memory region 202a from the memory cell 112 in the second memory region 202b. In further embodiments (not shown), the second etching process further etches a portion of the ILD layer 104 to form sidewalls of the ILD layer 104 laterally between the first memory region 202a and the second memory region 202b.

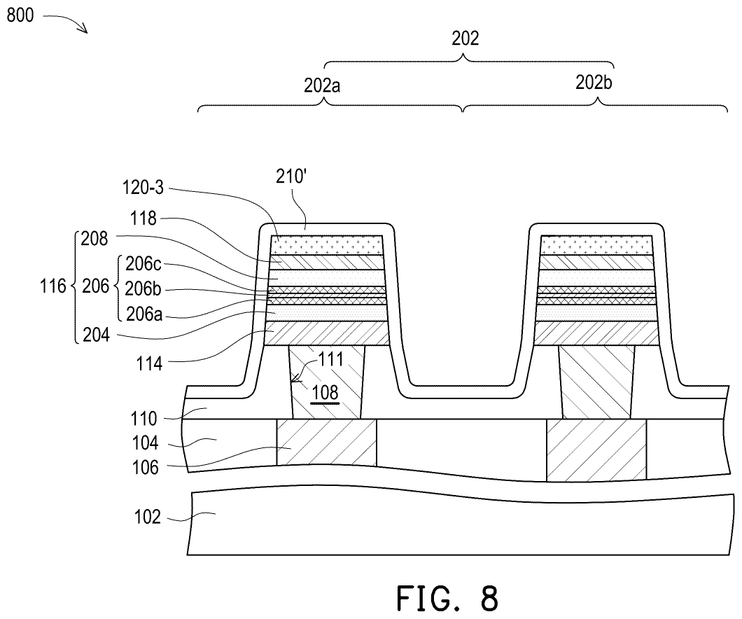

As illustrated by the cross-sectional view 800 of FIG. 8, a spacer layer 210′ is formed over the dielectric layer 110, the bottom electrode 114, the data storage structure 116, the top electrode 118, and the patterned hard mask 120-3, such that the spacer layer 210′ continuously extends to respective ones of the plurality of memory regions 202. The spacer layer 210′ may be formed by way of a deposition process (e.g., a chemical vapor deposition (CVD) process, a plasma enhanced CVD process, a physical vapor deposition process, or the like). In some embodiments, the spacer layer 210′ may be or otherwise include, for example, silicon dioxide, silicon nitride, titanium nitride, any other suitable material(s), or any combination of the foregoing.

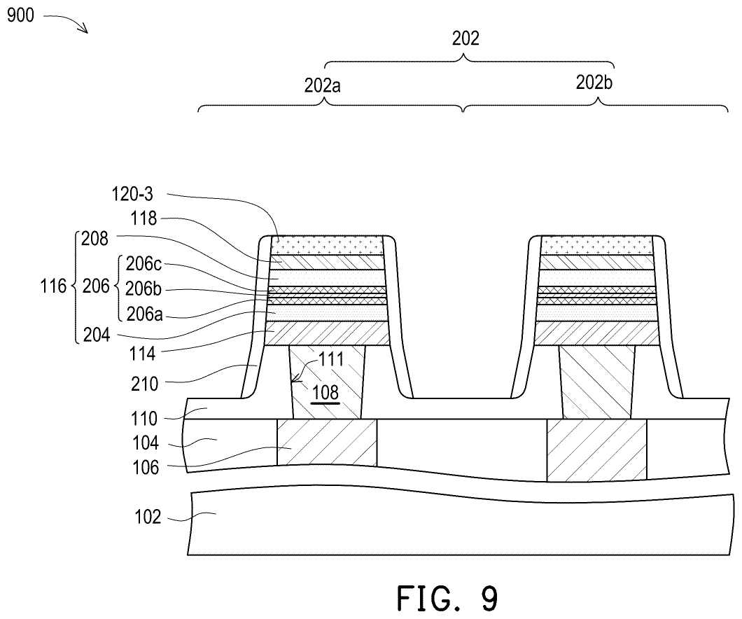

As illustrated by the cross-sectional view 900 of FIG. 9, the spacer layer 210′ is etched to form a sidewall spacer 210 along the sidewalls of the patterned hard mask 120-3, the sidewalls of the top electrode 118, the sidewalls of the data storage structure 116, and the sidewalls of the bottom electrode 114 of respective ones of the plurality of memory regions 202. In some embodiments, the sidewall spacer 210 continuously extends along the sidewalls of the dielectric layer 110 of respective ones of the plurality of memory regions 202. In some embodiments, laterally extending portions of the sidewall spacer 210 are formed along a top surface of the dielectric layer 110. In further embodiments, the laterally extending portions of the sidewall spacer 210 are removed by a removal process. In some embodiments (not shown), the sidewall spacer 210 continuously extends along the sidewalls of the ILD layer 104 of respective ones of the plurality of memory regions 202. The sidewall spacer 210 includes the same material as the spacer layer 210′. The removal process may be or otherwise include, for example, a wet etching process. In various embodiments, the wet etching process utilizes a wet etchant using hydrofluoric acid (HF), potassium hydroxide (KOH), an alkali wet etchant, or the like.

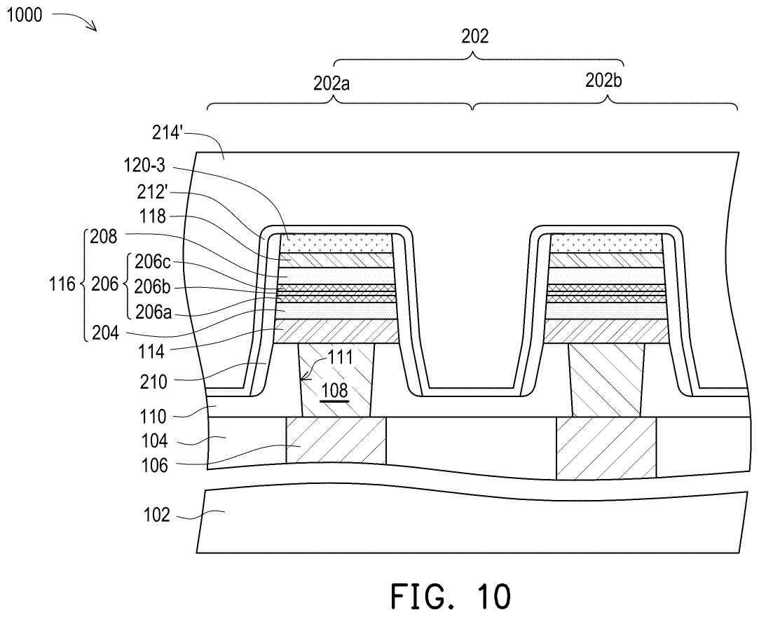

As illustrated by the cross-sectional view 1000 of FIG. 10, an etch stop layer 212′ is formed over the dielectric layer 110, the sidewall spacer 210 and the patterned hard mask 120-3, such that the etch stop layer 212′ continuously extends to respective ones of the plurality of memory regions 202, and the sidewall spacer 210 is sandwiched between the etch stop layer 212′ and the patterned hard mask 120-3. The etch stop layer 212′ may be formed to have a thickness ranging from 10 nanometers to 40 nanometers. The etch stop layer 212′ may be formed by way of a deposition process (e.g., a chemical vapor deposition (CVD) process, a plasma enhanced CVD process, a physical vapor deposition process, or the like). In some embodiments, the etch stop layer 212′ may be or otherwise include, for example, silicon dioxide, a nitride (e.g., silicon nitride, silicon oxynitride), a carbide (e.g., silicon carbide, silicon oxycarbide), some other suitable etch stop material(s), or a combination of the aforementioned materials.

As further illustrated by the cross-sectional view 1000 of FIG. 10, a dielectric layer 214′ is formed over the etch stop layer 212′ and continuously extends to respective ones of the plurality of memory regions 202. The dielectric layer 214′ may be formed by way of a deposition process (e.g., a chemical vapor deposition (CVD) process, a plasma enhanced CVD process, a physical vapor deposition process, or the like). In some embodiments, the dielectric layer 214′ may be or otherwise include, for example, silicon dioxide, silicon nitride, titanium nitride, any other suitable material(s), or any combination of the foregoing.

As illustrated by the cross-sectional view 1100A of FIG. 11A, a hole 123 is etched into the dielectric layer 214′, the etch stop layer 212′ and the patterned hard mask 120-3 over the top electrode 118 in respective ones of the plurality of memory regions 202 by a fourth etching process, thereby forming a dielectric layer 214, an etch stop layer 212 and a hard mask pattern 120 in each memory region 202. The fourth etching process may be or otherwise include, for example, a dry etching process. In some embodiments (not shown), the fourth etching process may be performed by forming a mask (e.g., a hard mask, a photoresist, or the like) over the dielectric layer 214′, then exposing the dielectric layer 214′ to an etchant according to the mask to form the holes 123. The mask is then removed after performing the fourth etching process.

The hole 123 extends to a top surface 118ts of the top electrode 118 such that the top surface 118ts of the top electrode 118 is exposed through the hole 123. The hard mask pattern 120 is a portion of the patterned hard mask 120-3 remained on the top electrode 118 after the fourth etching process is completed. A side surface 120a of the hard mask pattern 120 may be exposed through the hole 123. In addition, a side surface 212a of the etch stop layer 212 may be exposed through the hole 123. As illustrated by the top view 1100B of FIG. 11B, in some embodiments, the hard mask pattern 120 surrounds the hole 123 and has a ring shape, and may also be referred to as a hard mask ring 120.

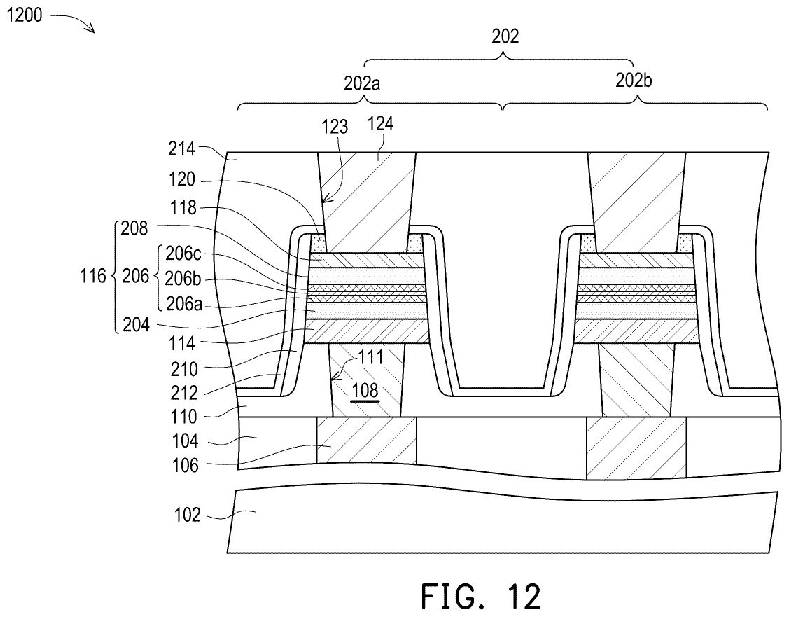

As illustrated by the cross-sectional view 1200 of FIG. 12, top electrode vias (TEVA) 124 are formed respectively in the holes 123. In some embodiments, the TEVAs 124 are formed by depositing a conductive material within respective ones of the plurality of memory regions 202. In various embodiments, the conductive material may be deposited by a deposition process that may be or otherwise include, for example, chemical vapor deposition, physical vapor deposition, sputtering, and/or a plating process (e.g., an electroplating process, an electro-less plating process). In some embodiments, the conductive material may be or otherwise include, for example, tungsten, nickel, cobalt, platinum, gold, iron, or some other suitable conductive material(s). A planarization process is subsequently performed to remove the conductive material from over a top surface of the dielectric layer 214′ to form the TEVA 124. The planarization process may be or otherwise include, for example, a chemical-mechanical planarization (CMP), grinding, an etch, or some other suitable process. In some embodiments, the TEVA 124 may have a height ranging from approximately 20 nanometers to approximately 150 nanometers, from approximately 30 nanometers to approximately 100 nanometers, from approximately 40 nanometers to approximately 80 nanometers, or other similar values.

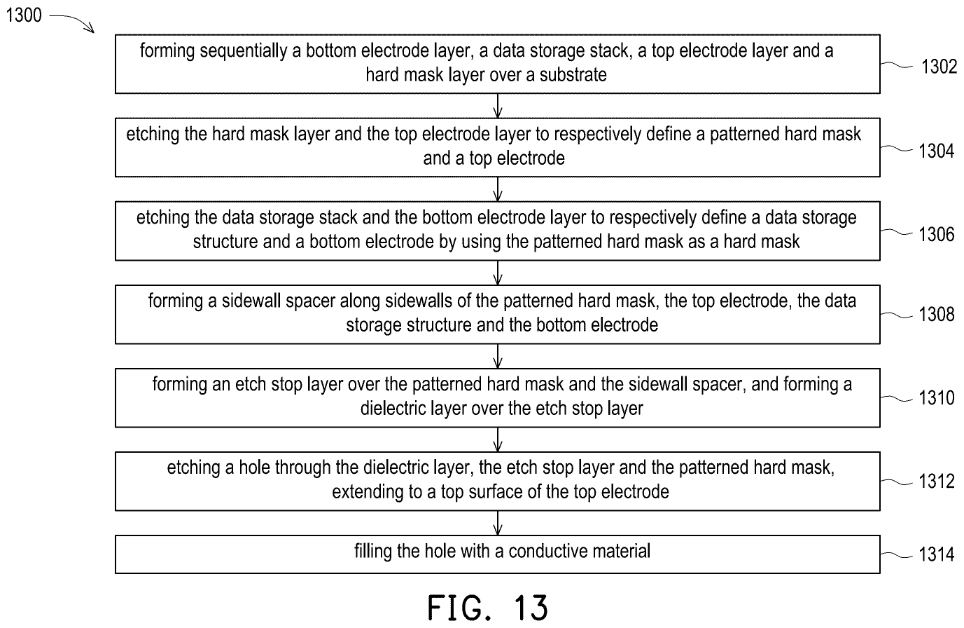

With respect to FIG. 13, a flowchart 1300 illustrates some embodiments of a method for forming a semiconductor device according to the present disclosure. The method may, for example, correspond to the method of FIGS. 4-12.

While the disclosed flowchart 1300 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 1302, a bottom electrode layer, a data storage stack, a top electrode layer and a hard mask layer are formed sequentially over a substrate. FIG. 4 and FIG. 5 illustrates cross-sectional views 400 and 500 of some embodiments corresponding to act 1302.

At act 1304, the hard mask layer and the top electrode layer are etched to respectively define a patterned hard mask and a top electrode. FIG. 6 illustrates a cross-sectional view 600 of some embodiments corresponding to act 1304.

At act 1306, the data storage stack and the bottom electrode layer are etched to respectively define a data storage structure and a bottom electrode by using the patterned hard mask as a hard mask. FIG. 7 illustrates a cross-sectional view 700 of some embodiments corresponding to act 1306.

At act 1308, a sidewall spacer is formed along sidewalls of the patterned hard mask, the top electrode, the data storage structure and the bottom electrode. FIG. 8 and FIG. 9 illustrate cross-sectional views 800 and 900 of some embodiments corresponding to act 1308.

At act 1310, an etch stop layer is formed over the patterned hard mask and the sidewall spacer, and a dielectric layer is formed over the etch stop layer. FIG. 10 illustrates a cross-sectional view 1000 of some embodiments corresponding to act 1310.

At act 1312, a hole is etched through the dielectric layer, the etch stop layer and the patterned hard mask, extending to a top surface of the top electrode. FIG. 11A and FIG. 11B illustrates respectively a cross-sectional view 1100A and a top view 1100B of some embodiments corresponding to act 1312.

At act 1314, the hole is filled with a conductive material such that a top electrode via (TEVA) is formed into the hole. FIG. 12 illustrates a cross-sectional view 1200 of some embodiments corresponding to act 1314.

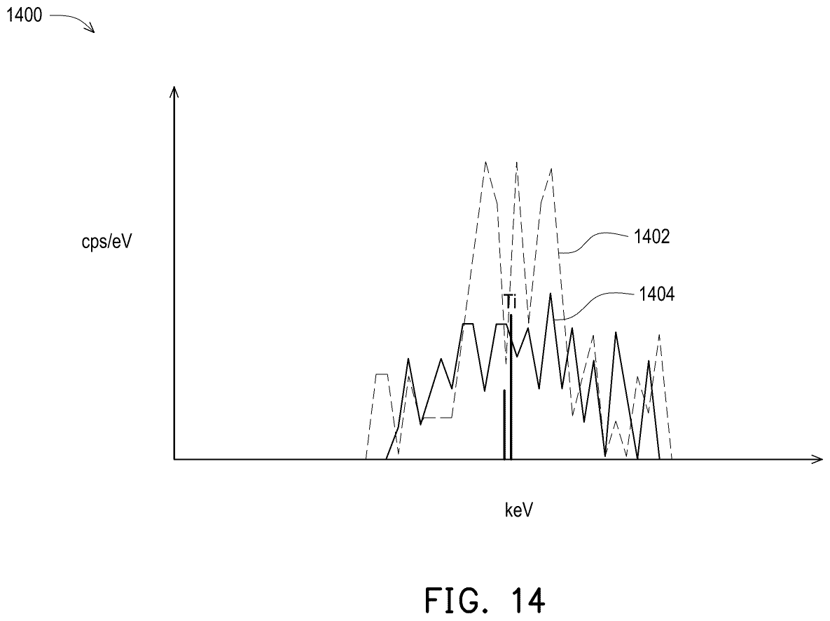

FIG. 14 illustrates a graphical representation 1400 of a titanium content analysis with respect to sidewalls of a data storage structure in a semiconductor device by using Energy Dispersive X-ray Analysis (EDX). A first line 1402 represents a conventional semiconductor device that is manufactured using a top electrode as a mask for an ion beam etching of the data storage structure and the bottom electrode. A second line 1404 represents a disclosed semiconductor device that is manufactured using a patterned hard mask as a mask for an ion beam etching of the data storage structure and the bottom electrode. The disclosed semiconductor device may be, for example, the semiconductor device of FIG. 1. The x-axis represents the energy used for the analysis, while the Y axis represents titanium content measured at various energies. As shown in FIG. 14, the titanium content measured in the disclosed semiconductor device is significantly reduced, as compared to that measured in the conventional semiconductor device. Thus, by using a patterned hard mask that includes a non-conductive material in the etching of the data storage structure and/or the bottom electrode, less conductive by-product from the etching process will be re-deposited on sidewalls of the data storage structure, thereby preventing shorting and improving reliability of the semiconductor device.

Accordingly, in some embodiments, the present disclosure relates to a semiconductor device. The semiconductor device includes a bottom electrode; a top electrode over the bottom electrode; a data storage structure disposed between the top electrode and the bottom electrode; a top electrode via (TEVA) electrically coupling the top electrode; and a hard mask pattern disposed over the top electrode and surrounding the TEVA.

In some embodiments, the hard mask pattern is completely overlapped with the top electrode. In some embodiments, a thickness of the top electrode is less than a thickness of the data storage structure. In some embodiments, the semiconductor device further includes a sidewall spacer extending along sidewalls of the bottom electrode, the data storage structure, the top electrode and the hard mask pattern, wherein the sidewall spacer protrudes upward beyond a top surface of the top electrode. In some embodiments, the hard mask pattern is sandwiched between the sidewall spacer and the TEVA. In some embodiments, the semiconductor device further includes an etch stop layer disposed on the sidewall spacer and the hard mask pattern, wherein the hard mask pattern is sandwiched between the etch stop layer and the top electrode. In some embodiments, the semiconductor device further includes a bottom electrode via (BEVA) underlying the bottom electrode and contacting a bottom surface of the bottom electrode. In some embodiments, an angle between an outer side surface of the hard mask pattern and a top surface of the top electrode ranges from 70° to 90° in a cross-sectional view cut through the hard mask pattern and the TEVA.

In other embodiments, the present disclosure relates to a semiconductor device. The semiconductor device includes a memory cell; a top electrode via (TEVA) overlying and contacting a top surface of the memory cell; a bottom electrode via (BEVA) underlying and contacting a bottom surface of the memory cell; and a hard mask ring extending along a bottom portion of a sidewall of the TEVA.

In some embodiments, the memory cell includes a bottom electrode; a top electrode over the bottom electrode; and a magnetic tunnel junction (MTJ) between the top electrode and the bottom electrode, wherein the hard mask ring contacting both a top surface of the top electrode and the sidewall of the TEVA. In some embodiments, the semiconductor device further includes a sidewall spacer contacting sidewalls of the memory cell and an outer side surface of the hard mask ring; an etch stop layer covering the sidewall spacer and the hard mask ring and contacting the sidewall of the TEVA; and a dielectric layer covering the etch stop layer and contacting the sidewall of the TEVA. In some embodiments, the semiconductor device further includes a memory cell region and a logic region, wherein the memory cell is disposed in the memory cell region, and an interconnect structure is disposed in the logic region at the same level as the memory cell. In some embodiments, the semiconductor device further includes a hard mask pattern surrounding the interconnect structure in the logic region.

In yet other embodiments, the present disclosure relates to a method for forming a semiconductor device. The method includes forming sequentially a bottom electrode layer, a data storage stack, a top electrode layer and a hard mask layer over a substrate; etching the hard mask layer and the top electrode layer to respectively define outer sidewalls of a patterned hard mask and a top electrode; etching the data storage stack and the bottom electrode layer to respectively define outer sidewalls of a data storage structure and a bottom electrode; etching a hole through the patterned hard mask, extending to a top surface of the top electrode; and filling the hole with a conductive material.

In some embodiments, the hard mask layer and the top electrode layer includes different materials. In some embodiments, a thickness of the hard mask layer is greater than a sum of a thickness of the data storage stack and a thickness of the bottom electrode layer. In some embodiments, the method further includes forming an etch stop layer over the patterned hard mask before etching the hole through the patterned hard mask, wherein the hole penetrates through the etch stop layer. In some embodiments, the method further includes forming a sidewall spacer along sidewalls of the patterned hard mask, the top electrode, the data storage structure and the bottom electrode before forming the etch stop layer, wherein the sidewall spacer is sandwiched between the etch stop layer and the patterned hard mask. In some embodiments, the method further includes forming a dielectric layer over the etch stop layer before etching the hole through the patterned hard mask, wherein the hole penetrates through the dielectric layer. In some embodiments, the hard mask layer includes silicon dioxide, silicon nitride, silicon carbide or a combination thereof.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a bottom electrode;
a top electrode over the bottom electrode;
a data storage structure disposed between the top electrode and the bottom electrode;
a top electrode via (TEVA) electrically coupling the top electrode; and
a hard mask pattern disposed over the top electrode and surrounding the TEVA.

2. The semiconductor device of claim 1, wherein the hard mask pattern is completely overlapped with the top electrode.

3. The semiconductor device of claim 1, wherein a thickness of the top electrode is less than a thickness of the data storage structure.

4. The semiconductor device of claim 1, further comprising a sidewall spacer extending along sidewalls of the bottom electrode, the data storage structure, the top electrode and the hard mask pattern, wherein the sidewall spacer protrudes upward beyond a top surface of the top electrode.

5. The semiconductor device of claim 4, wherein the hard mask pattern is sandwiched between the sidewall spacer and the TEVA.

6. The semiconductor device of claim 4, further comprising an etch stop layer disposed on the sidewall spacer and the hard mask pattern, wherein the hard mask pattern is sandwiched between the etch stop layer and the top electrode.

7. The semiconductor device of claim 1, further comprising a bottom electrode via (BEVA) underlying the bottom electrode and contacting a bottom surface of the bottom electrode.

8. The semiconductor device of claim 1, wherein an angle between an outer side surface of the hard mask pattern and a top surface of the top electrode ranges from 70° to 90° in a cross-sectional view cut through the hard mask pattern and the TEVA.

9. A semiconductor device, comprising:
a memory cell;
a top electrode via (TEVA) overlying and contacting a top surface of the memory cell;
a bottom electrode via (BEVA) underlying and contacting a bottom surface of the memory cell; and
a hard mask ring extending along a bottom portion of a sidewall of the TEVA.

10. The semiconductor device of claim 9, wherein the memory cell comprises:
a bottom electrode;
a top electrode over the bottom electrode; and
a magnetic tunnel junction (MTJ) between the top electrode and the bottom electrode,
wherein the hard mask ring contacting both a top surface of the top electrode and the sidewall of the TEVA.

11. The semiconductor device of claim 9, further comprising:
a sidewall spacer contacting sidewalls of the memory cell and an outer side surface of the hard mask ring;
an etch stop layer covering the sidewall spacer and the hard mask ring and contacting the sidewall of the TEVA; and
a dielectric layer covering the etch stop layer and contacting the sidewall of the TEVA.

12. The semiconductor device of claim 9, further comprising a memory cell region and a logic region, wherein the memory cell is disposed in the memory cell region, and an interconnect structure is disposed in the logic region at the same level as the memory cell.

13. The semiconductor device of claim 12, further comprising a hard mask pattern surrounding the interconnect structure in the logic region.

14. A method for forming a semiconductor device, comprising:
forming sequentially a bottom electrode layer, a data storage stack, a top electrode layer and a hard mask layer over a substrate;
etching the hard mask layer and the top electrode layer to respectively define a patterned hard mask and a top electrode;
etching the data storage stack and the bottom electrode layer to respectively define a data storage structure and a bottom electrode by using the patterned hard mask as a hard mask;
etching a hole through the patterned hard mask, extending to a top surface of the top electrode; and
filling the hole with a conductive material.

15. The method of claim 14, wherein the hard mask layer and the top electrode layer comprises different materials.

16. The method of claim 14, wherein a thickness of the hard mask layer is greater than a sum of a thickness of the data storage stack and a thickness of the bottom electrode layer.

17. The method of claim 14, further comprising forming an etch stop layer over the patterned hard mask before etching the hole through the patterned hard mask, wherein the hole penetrates through the etch stop layer.

18. The method of claim 17, further comprising forming a sidewall spacer along sidewalls of the patterned hard mask, the top electrode, the data storage structure and the bottom electrode before forming the etch stop layer, wherein the sidewall spacer is sandwiched between the etch stop layer and the patterned hard mask.

19. The method of claim 17, further comprising forming a dielectric layer over the etch stop layer before etching the hole through the patterned hard mask, wherein the hole penetrates through the dielectric layer.

20. The method of claim 14, wherein the hard mask layer comprises silicon dioxide, silicon nitride, silicon carbide or a combination thereof.
